(19) United States
(12) Patent Application Publication
(10) Pub. No.: US 2018/0233321 A1
(43) Pub. Date: Aug. 16, 2018

(54) ION DIRECTIONALITY ESC

(71) Applicant: Lam Research Corporation, Fremont, CA (US)

(72) Inventor: James E. CARON, Tracy, CA (US)

(21) Appl. No.: 15/435,046

(22) Filed: Feb. 16, 2017

(51) Int. Cl. H01J 37/20; H01L 21/67; H01L 21/683; H05B 3/06

(52) U.S. Cl. CPC H01J 37/20; H01L 21/67103; H01L 21/6833; H05B 2203/005; H01J 2237/2001; H01J 2237/334; H05B 3/06

(57) ABSTRACT

A substrate support for supporting a substrate within a semiconductor processing chamber is provided. A substrate support body is provided. At least one resistive heating element is embedded in or on the substrate support body comprising a first heating current path within or on the substrate and a second heating current path within or on the substrate, wherein the first heating current path is within 4 mm from the second heating current path, and the current flowing through the first current path is in an opposite direction of the current flowing through the second heating current path.

### BACKGROUND

The present disclosure relates to the manufacturing of semiconductor devices. More specifically, the disclosure relates plasma processing chamber for manufacturing semiconductor devices.

During semiconductor wafer processing, semiconductor wafers are supported by chucks, which may have temperature control. The temperature control may be provided by resistive heating elements.

### SUMMARY

To achieve the foregoing and in accordance with the purpose of the present disclosure, a substrate support for supporting a substrate within a semiconductor processing chamber is provided. A substrate support body is provided. At least one resistive heating element is embedded in or on the substrate support body comprising a first heating current path within or on the substrate and a second heating current path within or on the substrate, wherein the first heating current path is within 4 mm from the second heating current path, and the current flowing through the first current path is in an opposite direction of the current flowing through the second heating current path.

In another manifestation, a substrate support for supporting a substrate within a semiconductor processing chamber is provided. A substrate support body is provided. At least one resistive heating element is embedded in or on the substrate support body comprising a first heating current path within or on the substrate and a second heating current path within or on the substrate, antiparallel and within 4 mm of the first heating current path.

These and other features of the present disclosure will be described in more detail below in the detailed description of the disclosure and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 schematically illustrates an example of a plasma processing system, which may use an embodiment.

FIG. 2 is a top schematic view of the ESC with a heating element, according to an embodiment.

FIG. 3 is an electrical schematic of an electronic control that is used in a heat power supply of an embodiment.

FIG. 4 is a top schematic view of the ESC with a heating element in another embodiment.

FIG. 5 is a top schematic view of the ESC with a heating element in another embodiment.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

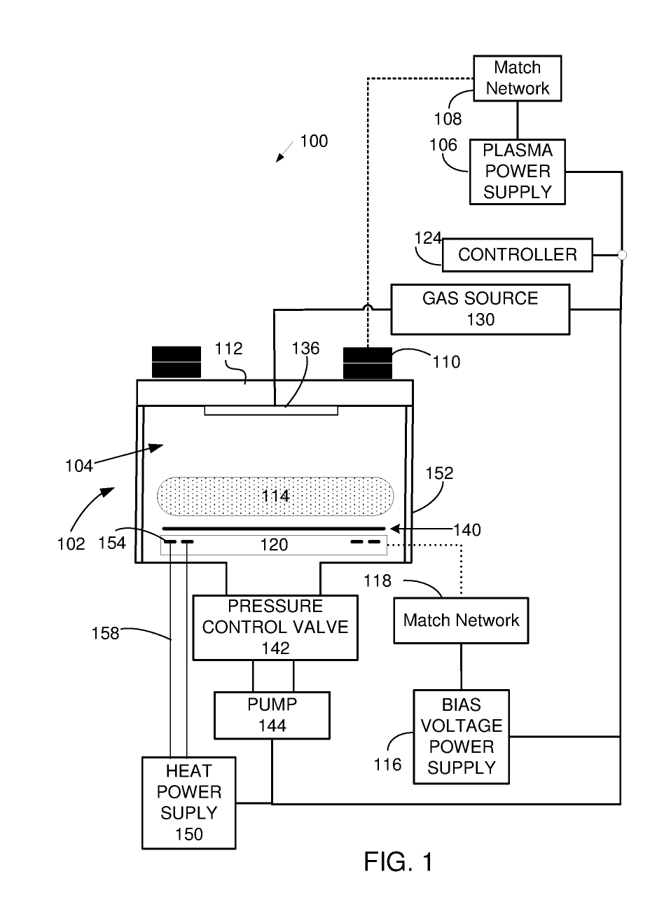

To facilitate understanding, FIG. 1 schematically illustrates an example of a plasma processing system 100, which may use an embodiment. The plasma processing system may be used to etch a substrate 140 with a stack in accordance with one embodiment of the present disclosure. The plasma processing system 100 includes a plasma reactor 102 having a plasma processing chamber 104, enclosed by a chamber wall 152. A plasma power supply 106, tuned by a match network 108, supplies power to a TCP coil 110 located near a power window 112 to create a plasma 114 in the plasma processing chamber 104 by providing an inductively coupled power. The TCP coil (upper power source) 110 may be configured to produce a uniform diffusion profile within the plasma processing chamber 104. For example, the TCP coil 110 may be configured to generate a toroidal power distribution in the plasma 114. The power window 112 is provided to separate the TCP coil 110 from the plasma processing chamber 104 while allowing energy to pass from the TCP coil 110 to the plasma processing chamber 104. A wafer bias voltage power supply 116 tuned by a match network 118 provides power to an electrostatic chuck (ESC) 120 to set the bias voltage on the substrate 140 which is supported over the ESC 120. A controller 124 sets points for the plasma power supply 106 and the wafer bias voltage power supply 116.

The plasma power supply 106 and the wafer bias voltage power supply 116 may be configured to operate at specific radio frequencies such as, 13.56 MHz, 27 MHz, 40 MHz, 60 MHz, 2 MHz, 400 kHz, or combinations thereof. Plasma power supply 106 and wafer bias voltage power supply 116 may be appropriately sized to supply a range of powers in order to achieve desired process performance. For example, in one embodiment, the plasma power supply 106 may supply the power in a range of 50 to 5000 Watts, and the wafer bias voltage power supply 116 may supply a bias voltage of in a range of 20 to 2000 V. In addition, the TCP coil 110 may be comprised of two or more sub-coils, and the ESC may be comprised of two or more sub-electrodes, which may be powered by a single power supply or powered by multiple power supplies.

As shown in FIG. 1, the plasma processing system 100 further includes a gas source/gas supply mechanism 130. The gas source/gas supply mechanism 130 provides gas to a gas feed 136 in the form of a shower head. The process gases and byproducts are removed from the plasma processing chamber 104 via a pressure control valve 142 and a pump 144, which also serve to maintain a particular pressure within the plasma processing chamber 104. The gas source/gas supply mechanism 130 is controlled by the controller 124.

A heater power supply 150 is controlled by the controller 124. The heater power supply 150 is electrically connected by power leads 158 to one or more resistive heating elements 154. A Kiyo by Lam Research Corp. of Fremont, Calif., may be used to practice an embodiment.

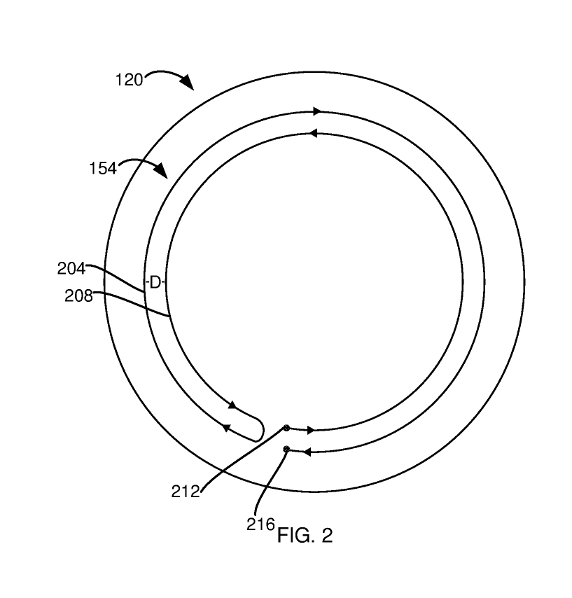

FIG. 2 is a top schematic view of the ESC 120 with a heating element 154.

The heating element 154 in this example is a single conductive element forming almost two complete loops with a first heating current path 204 forming an almost complete first loop and a second heating current path 208 forming an almost complete second loop. The heating element 154 is electrically connected to power leads at a first contact point 212 at a first end of the heating element 154 and a second contact point 216 at a second end of the heating element 154 opposite from the first end of the heating element 154. In this example, the distance labeled “D” between the first current path 204 and the second current path 208 is less than 4 mm. In this example, the first current path 204 is within 4 mm from the second current path 208 along 100% of the length of the first current path 204, and the second current path 208 is within 4 mm from the first current path 204 along 100% of the second current path 208. In this example, because a second end of the first current path 204 is electrically connected to a first end of the second current path 208, and since the second current path 208 loops in a reverse direction to the first current path 204, current flows through the heating element 154 in a way so that the current in the first current path 204 is antiparallel to current flow in the second current path 208. In this embodiment the first heating current path 204 and the second heating current path 208 are in series.

In operation, a substrate 140 is mounted on the ESC 120. A voltage is provided by the heat power supply 150 to create a current in the heating element with the current flow indicated by the arrows in FIG. 2. A process gas is flowed into the processing chamber. RF power is provided to form the process gas into a plasma. A bias voltage is provided to the ESC 120 by the bias voltage power supply 116, which causes ions from the plasma to accelerate to the substrate 140, so that the substrate is processed.

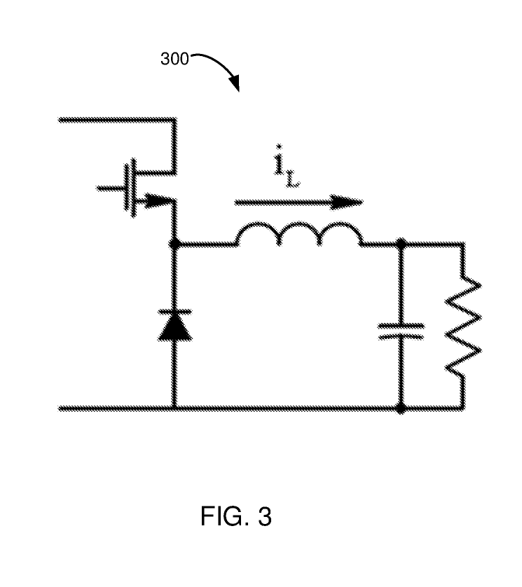

FIG. 3 is an electrical schematic of an electronic control 300 that is used in the heat power supply 150, as shown in FIG. 1. The electronic control 300 is called a buck converter. The buck converter provides a DC voltage to the heating element. The buck converter is used to lower a DC voltage. In the alternative, if a DC voltage is to be increased before applying the DC voltage to the heating element, a boost converter may be used. By providing a DC voltage, this embodiment solves the problems with the prior art by using a fixed polarity heater voltage and a separate means for canceling the magnetic field generated by the heater elements. The magnetic fields generated by the heater elements are canceled by routing the currents in different heating elements being in close proximity to each other, with current flowing in opposite directions.

Prior art systems provide heating elements where the current flows parallel, instead of antiparallel. The current flowing through the heating elements generates a magnetic field which causes a force on the ions perpendicular to their direction of travel as the ions are accelerated through the plasma sheath to the wafer. This force would tend to force the ion trajectory in a direction non normal to the wafer surface, which would limit high aspect ratio etching. To minimize the process impact of the ion trajectory being shifted non normal to the surface, the prior art heaters were powered with high frequency alternating current. The alternating heater current reverses the direction of the magnetic field, which then reverses the force and direction of the ion trajectory. The net effect is to sweep the ion trajectory back and forth relative to the un-magnetized or zero current condition to improve uniformity. The problems with this approach are as follows: 1) The ion trajectories are swept non normal to the wafer surface potentially impacting the process. 2) The magnetic field lines are not parallel to the wafer near the center and edge of the wafer, which can contribute to additional center and edge uniformity issues. 3) A DC powered heater may not be an option for process requiring high ion directionality because the shift in ion direction will always be to one side. 4) The magnetic fields generated by the alternating heater polarity are not fast enough to average out any shift in ion trajectory caused by the fields. Although the alternating current is at a high frequency above 20 kilohertz, it would be desirable to provide an alternating frequency of greater than 1 MHz in order to average out shifts in ion trajectory.

The prior art used alternating polarity voltage, where heater power is controlled through phase angle or cycle skipping control of the 50 or 60 Hz AC line voltage. Other configurations attempt to use high frequency (300 Hz) variable duty cycle, alternating polarity voltage for controlling power on the ESC heaters. The high frequency and variable duty cycle are used to provide faster response and finer control of the heater power. The alternating polarity of the heater power is used to minimize the impact of the magnetic field generated from the heater current on process uniformity. The problems with the high frequency alternating polarity approach are: 1) The alternating polarity approach requires additional switching components to continually switch the direction of the heater current. 2) There is an increased risk of device failure due to shoot through if two series switching devices are turned on at the same time. 3) The alternating polarity approach requires that the device, parasitic and load capacitance be charged and discharged on each cycle resulting in higher switching losses, lower reliability and increased RF interference. 4) The heater voltage and current are more difficult to determine due to the complex waveforms generated. (Measurements of the voltage and current can be useful for calculating heater power and resistance of the heater coil). 5) The magnetic fields generated by the alternating heater polarity are not fast enough to average out any shift in ion trajectory caused by the fields.

The problems with the prior art are addressed by: 1) Use of a fixed polarity heater that reduces the heater control component count, because the need to switch the polarity of the output voltage is no longer required. This allows replacing an H bridge configuration with a simple buck converter. 2) The risk of device failure due to shoot through is eliminated because the devices are not connected in series across the converter input voltage. 3) Switching losses and RFI are reduced because the device, parasitic and load capacitance, do not need to be charged and discharged on each cycle. 4) Measurements of the heater voltage and current are simplified due to the simpler voltage and current waveforms generated with the single polarity heater power source. 5) To minimize the effect of the fixed magnetic field on high aspect ratio features, two heating elements in close proximity are powered with current flowing in opposite direction so the magnetic field generated by the separate heating elements are canceled out.

The above embodiment would significantly reduce the shift in ion trajectory caused by the heater current by canceling out the magnetic field generated by the current flowing through the heater, where the method used to cancel the magnetic fields is to flow current in the heating elements in opposite (antiparallel) directions.

Cancellation of the magnetic fields will be most effective when the heating elements are in close proximity to each other. The power source in the above embodiment may be DC or AC, since if an alternating current is provided, the heater element would still have antiparallel currents. If an AC is used, the AC would be at a low frequency under 10 KHz. A low frequency AC would be easier to switch and a high frequency AC is not needed to cancel magnetic effects.

By canceling the magnetic field and reducing the shift in ion trajectory, the above embodiment provides: 1) An improvement in high aspect ratio processes. 2) An improvement in center and edge uniformity. 3) The ability to use DC powered heaters which could simplify the control electronics.

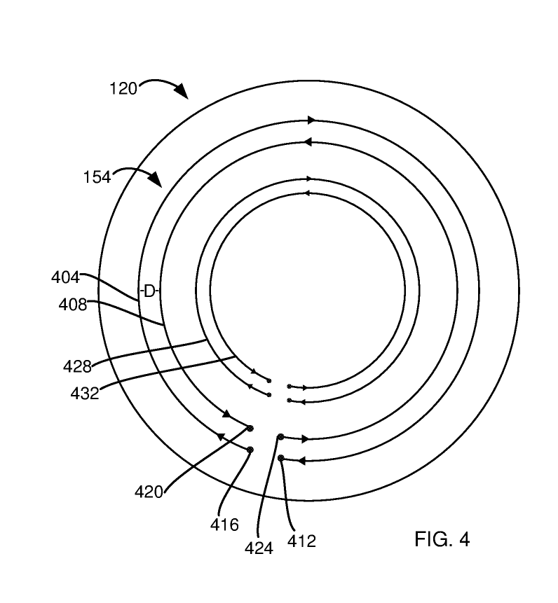

FIG. 4 is a top schematic view of the ESC 120 with a heating element 154 in another embodiment. The heating element 154 in this example is two separate conductive elements forming almost two complete loops with a first heating current path 404 forming an almost complete first loop and a second heating current path 408 forming an almost complete second loop. The first heating current path 404 is electrically connected to power leads at a first contact point 412 at a first end of the first heating current path 404 and a second contact point 416 at a second end of the first heating current path 404 opposite from the first end of the first heating current path 404. The second heating current path 408 is electrically connected to power leads at a third contact point 420 at a first end of the second heating current path 408 and a fourth contact point 424 at a second end of the second heating current 408 path opposite from the first end of the second heating current path 408. In this example, the distance labeled “D” between the first current path 404 and the second current path 408 is less than 4 mm. In this example, the first current path 404 is within 4 mm from the second current path 408 along 100% of the length of the first current path 404. In this example, the leads are connected to the first heating current path 404 and the second heating current path 408 in a way that causes current to flow through the heating element 154 in a way so that the current in the first current path 404 is antiparallel to current flow in the second current path 408, as shown by the arrows indicating flow of current. This may be accomplished by connecting the first contact point 412 and the third contact point 420 to the same first terminal of the heat power supply 150 or the same power lead and by connecting the second contact point 416 and the fourth contact point 424 to the same second terminal of the heat power supply 150 or the same power lead. In this embodiment, the first current heating path 404 and the second current heating path 408 are electrically parallel circuits with current in antiparallel directions.

In this embodiment, a second heating element has a third current path 428 and a fourth current path 432. The third and fourth current paths 428, 432 also have antiparallel current path flows, so that they are able to sufficiently cancel each other's magnetic fields. The first heating element 154 may be in a first heating zone, and the second heating element may be in a second heating zone. The different heating zones may have different amounts of currents to provide two independently controlled temperature controls. In another embodiment, the first, second, third, and fourth current paths may be electrically connected to form a single heating element that are all controlled together to provide a single temperature zone.

In other embodiments, the buck converter may be replaced with another type of converter. Preferably, the first heating current path is within a distance D of the second heating current path for at least 50% of the length of the first heating current path and the second heating current path is within the distance D of the first heating current path for at least 50% of the length of the second heating path. More preferably, the first heating current path is within a distance D of the second heating current path for at least 75% of the length of the first heating current path and the second heating current path is within the distance D of the first heating current path for at least 75% of the length of the second heating path. Most preferably, the first heating current path is within a distance D of the second heating current path for 100% of the length of the first heating current path and the second heating current path is within the distance D of the first heating current path for 100% of the length of the second heating path. Preferably, the first heating current path is within a distance D of the second heating current path for a length equal to a radius of the ESC. More preferably, the first heating current path is within a distance D of the second heating current path for a length equal to a diameter of the ESC. Preferably, the first heating current path is within a distance D of the second heating current path for a length of at least 5 cm. Preferably, D is 4 mm. More preferably, D is 2 mm.

In order to sufficiently cancel magnetic fields in adjacent current paths, the currents must be substantially equal. Preferably, substantially equal current has a difference of less than 25%.

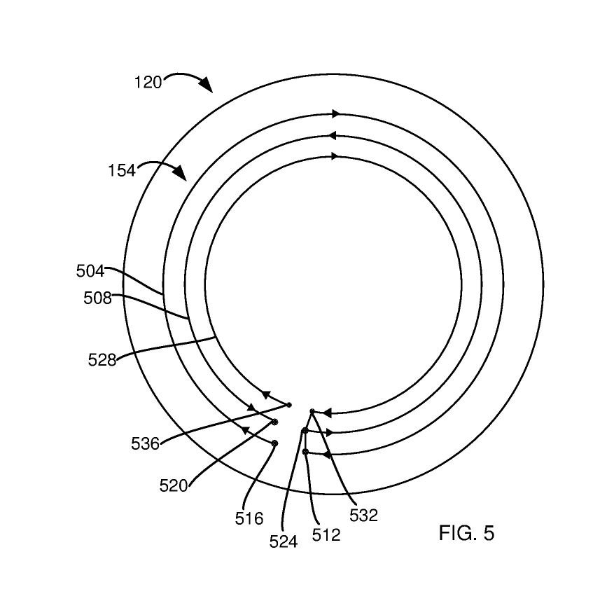

FIG. 5 is a top schematic view of the ESC 120 with a heating element 154 in another embodiment. The heating element 154 in this example is three separate conductive elements forming almost three complete loops, with a first heating current path 504 forming an almost complete first loop, a second heating current path 508 forming an almost complete second loop, and a third heating current path 528 forming an almost complete third loop. The first heating current path 504 has a first end 512 and a contact point 516 at a second end of the first heating current path 504 opposite from the first end 512 of the first heating current path 504. The second heating current path 508 has a contact point 520 at a first end of the second heating current path 508 and a second end 524 opposite from the first end of the second heating current path 508. The third heating current path 528 has a first end 532 and a contact point 536 at a second end of the third heating current path 528 opposite from the first end 532 of the third heating current path 528. In this example, the first current path 504, the second current path 508, and third current path 528 are all within 4 mm of each other along 100% of the length of the first current path 504. In this example, the leads are connected to the first heating current path 504, the second heating current path 508, and the third heating current path 528 in a way that causes current to flow through the heating element 154 so that the current in the first current path 504 is antiparallel to current flow in the second current path 508 and the current flow in the second current path 508 is antiparallel to the current flow in the third current path 528, as shown by the arrows indicating flow of current. In addition, the sum of the current in the first current path 504 and the third current path 528 is substantially equal to the current in the second current path 508. This may be accomplished by connecting contact point 520 to the first terminal of the heat power supply 150 and connecting contact point 516 and contact point 536 to the second terminal of the heat power supply 150 and connecting the first end 512 of the first heating current path 504, the second end 524 of the second heating current path 508, and the first end 532 of the third heating current path 528 together. In addition, the current of the second heating current path would equal the sum of the current of the first heating current path and the current of the third heating current path.

Other configurations may be provided that use adjacent current paths with antiparallel current flow in order to substantially cancel magnetic fields generated by the current paths. Such systems improve high aspect ratio etching by reducing magnetic fields generated by resistive heating elements. In other configurations, the substrate support may be used in a capacitively coupled or other powered plasma processing chamber. In other embodiments, first and second heating current paths may be made of a plurality of conductive paths and the sum of the currents flowing through the first heating current paths are within 25% of the sum of the currents flowing through the second heating current paths, so that the sums are substantially equal. Other substrate supports may be used instead of an ESC. For example, the substrate support may use a mechanical chuck system.

In some embodiments, the heating current paths form most of a circumference of a circle or form a spiral. Such a configuration allows for separately controlled inner zones and outer zones. In other embodiments, the heating current paths may be linear or may have other configurations. The resistive heating element may be embedded in the substrate support body of the ESC or embedded on a surface of the substrate support body.

While this disclosure has been described in terms of several preferred embodiments, there are alterations, permutations, modifications, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure.

What is claimed is:

1. A substrate support for supporting a substrate within a semiconductor processing chamber, wherein the substrate support comprises:
a substrate support body; and
at least one resistive heating element embedded in or on the substrate support body comprising a first heating current path within or on the substrate support body and a second heating current path within or on the substrate support body, wherein the first heating current path is within 4 mm from the second heating current path, and the current flowing through the first current path is in an opposite direction of the current flowing through the second heating current path.

2. The substrate support, as recited in claim 1, wherein the first heating current path has a length and wherein for at least half of the length of the first heating current path, the first heating current path is within 4 mm from the second heating current path.

3. The substrate support, as recited in claim 1, wherein the first heating current path has a length and wherein for at least half of the length of the first heating current path, the first heating current path is within 2 mm from the second heating current path.

4. The substrate support, as recited in claim 3, wherein the first heating current path and the second heating current path are configured to carry substantially equal amounts of current.

5. The substrate support, as recited in claim 4, further comprising a DC power source electrically connected to the resistive heating element.

6. The substrate support, as recited in claim 5, further comprising a buck converter or boost converter electrically connected between the DC power source and the resistive heating element.

7. The substrate support, as recited in claim 4, further comprising an AC power source electrically connected to the resistive heating element.

8. The substrate support, as recited in claim 3, wherein the first and second heating current paths are made of one or more of conductive paths and the sum of the currents flowing through the first heating current paths are within 25% of the sum of the currents flowing through the second heating current paths.

9. The substrate support, as recited in claim 2, further comprising a low frequency AC power source electrically connected to the resistive heating element.

10. The substrate support, as recited in claim 1, wherein the first heating current path and the second heating current path are configured to carry substantially equal amounts of current.

11. The substrate support, as recited in claim 1, further comprising a DC power source electrically connected to the resistive heating element.

12. The substrate support, as recited in claim 11, further comprising a buck converter or boost converter electrically connected between the DC power source and the resistive heating element.

13. The substrate support, as recited in claim 1, further comprising an AC power source electrically connected to the resistive heating element.

14. The substrate support, as recited in claim 1, wherein the first and second heating current paths are made of one or more of conductive paths and the sum of the currents flowing through the first heating current paths are within 25% of the sum of the currents flowing through the second heating current paths.

15. The substrate support, as recited in claim 1, further comprising a low frequency AC power source electrically connected to the resistive heating element.

16. A substrate support for supporting a substrate within a semiconductor processing chamber, wherein the substrate support comprises:
a substrate support body; and
at least one resistive heating element embedded in or on the substrate support body comprising a first heating current path within or on the substrate support body and a second heating current path within or on the substrate support body, antiparallel and within 4 mm of the first heating current path.

17. The substrate support, as recited in claim 16, wherein the first heating current path has a length and wherein for at least half of the length of the first heating current path, the first heating current path is antiparallel and within 4 mm from the second heating current path.

18. The substrate support, as recited in claim 17, further comprising a DC power source electrically connected to the resistive heating element.
